(19) United States
(12) Patent Application Publication
(10) Pub. No.: US 2006/0267047 A1
(43) Pub. Date: Nov. 30, 2006

(54) Hetero-junction bipolar transistor and manufacturing method of the same

(75) Inventor: Keiichi Murayama, Toyama (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/406,581

(22) Filed: Apr. 17, 2006

(30) Foreign Application Priority Data
May 26, 2005 (JP) 2005-153206

(51) Int. Cl. H01L 31/00

(52) U.S. Cl. 257/197

(57) ABSTRACT

Ion implantation is performed on a collector area under an external base area, and a capacitance film is provided on the external base area above the collector area.

### FIELD OF THE INVENTION

The present invention relates to a hetero-junction bipolar transistor used as an RF analog device and a manufacturing method of the same.

### BACKGROUND OF THE INVENTION

Hetero-junction bipolar transistors (HBTs), in which semiconductors with large band gaps are used for emitters, have been put into practical use as RF analog devices for cellular phones and so on. Particularly InGaP/GaAs HBTs using InGaP for emitters are reliable devices with less temperature dependence, and the usage thereof is expected to be wider in the future.

The use of InGaP/GaAs HBTs has expanded in recent years. As to cellular phone transmitter amplifiers, studies have been conducted on the actual use of such HBTs as power devices in the transmission units of GSM terminals as well as conventional CDMA terminals.

When conventional HBTs are used as high power transistors, about 5 to 100 HBTs, each of which acts as a unit cell, are connected in parallel. However, a rise in temperature varies among the plurality of HBTs due to variations in operating states, heat distributions, and so on. In this case, an HBT at a high temperature has higher emitter current and further rises in temperature. In the end, the HBT causes thermal runaway and is destroyed. This phenomenon is more likely to occur as output increases, and a serious problem may occur particularly in HBTs for high-output GSMs.

A general solution for this problem is to place a ballast resistor on the base input terminal of each HBT to improve uniformity of operations.

However, when a ballast resistor is simply placed, high frequency characteristics are degraded by the passage of a high-frequency input signal through the ballast resistor.

One solution for this problem is disclosed in, for example, the specification of U.S. Pat. No. 5,608,353. A capacitance (MIM capacitance) permitting only the passage of RF input is formed for each HBT cell and a high-frequency input signal is inputted through the capacitance, so that high frequency characteristics are not degraded.

However, this solution increases an area of a used MIM capacitance and requires a complicated layout, thereby considerably increasing a chip area.

When SiN=200 nm is used for an ordinary MIM capacitance film, a large capacitance of about 100×100 μm is formed for an HBT having an emitter size of 120 μm².

One solution for this problem is disclosed in, for example, Japanese Patent Laid-Open No. 2004-111941 in which fracture resistance is improved by a structure comprising C and R in an HBT. The following will briefly discuss this solution.

This bipolar transistor comprises a first semiconductor layer having an intrinsic base area and an external base area, a second semiconductor layer which is formed on the first semiconductor layer and has an emitter area on the intrinsic base area, a capacitance film formed on the external base area of the first semiconductor layer, and a base electrode a part of which is formed on the capacitance film on the first semiconductor layer and the other part of which is connected to the external base area. With this structure, a high-frequency input signal inputted to the base electrode reaches the intrinsic base area through the capacitance film. Thus, the high frequency characteristics of the input signal are not degraded by the resistance of the external base area. Since direct current reaches the intrinsic base area through the external base area, a design can be made with a high resistance relative to the direct current. Hence, the thermal stability of the bipolar transistor can be improved by using a base resistor as a ballast resistor.

### DISCLOSURE OF THE INVENTION

However, the capacitance film and the ballast resistor are formed in the external base area in the structure comprising C and R, and thus a collector-base capacitance (Cbc) increases with the expanded external base area.

In order to input high frequency characteristics without loss according to the conventional techniques, the capacitance film requires a capacitance area almost equal to that of an HBT on the assumption that the InGaP film of the capacitance film has a thickness of 30 nm and a permittivity of 11.8. However, the collector-base capacitance (Cbc) is present under the capacitance film and thus the Cbc is doubled by a combined area of the intrinsic base area of the HBT and the external base area of the capacitance. As a result, fmax serving as an index of high frequency characteristics decreases.

For reference, fmax is expressed by the equation below:
fmax=(ft/8πCbcRb)1/2

In order to solve the problem, an object of the present invention is to improve thermal stability and fracture resistance while suppressing an increase in chip area and degradation of high frequency characteristics.

In order to attain the object, a hetero-junction bipolar transistor of the present invention comprises a substrate and semiconductor layers stacked on the substrate, the transistor comprising a sub-collector layer of a first conductivity type formed on the substrate, a collector layer of the first conductivity type formed on the sub-collector layer, a base layer of a second conductivity type which is formed on the collector layer and including an intrinsic base area and an external base area, an emitter layer of the first conductivity type formed on the intrinsic base area, a capacitance film formed on the external base area, an upper electrode formed on the capacitance film, and a first base electrode formed in the external base area, wherein ion implantation is performed on the sub-collector layer and the collector layer under the capacitance film.

The sub-collector layer and the collector layer under the capacitance film are electrically insulated by ion implantation.

The first base electrode is formed in an area at a fixed distance or more from a boundary of the external base area and the intrinsic base area.

The transistor further comprises a second base area formed near the boundary of the external base area and the intrinsic base area, and the capacitance film is formed between the first base electrode and the second base electrode.

A non-ion implantation area is formed under the second base electrode.

The capacitance film is made of a semiconductor material of the first conductivity type.

The capacitance film is formed by extending the emitter layer to the external base area.

The capacitance film is made of InGaP or AlGaAs.

The upper electrode is made of a metal making Schottky contact with the emitter layer.

A manufacturing method of the hetero-junction bipolar transistor of the present invention is a method of manufacturing a hetero-junction bipolar transistor comprising a substrate and semiconductor layers stacked on the substrate, the method comprising: forming a sub-collector layer of a first conductivity type on the substrate, forming a collector layer of the first conductivity type on the sub-collector layer, forming on the collector layer a base layer of a second conductivity type including an intrinsic base area and an external base area, forming an emitter layer of the first conductivity type on the intrinsic base area, forming a capacitance film on the external base area, implanting ions into the sub-collector layer and the collector layer under the capacitance film, forming an upper electrode on the capacitance film, and forming a first base electrode in the external base area.

Implantation ion species are He or H ions, and the method comprises at least performing ion implantation at an acceleration voltage of 200 keV or higher.

The method further comprises forming a second base area near the boundary of the external base area and the intrinsic base area.

The second base electrode is formed on the base area where ion implantation is not performed.

The emitter layer is made of InGaP or AlGaAs and the emitter layer is formed by selective etching.

The first base electrode and the second base electrode are made of Pt or Pd and diffused by thermal diffusion from above the capacitance film to the base layer.

The upper electrode is made of a metal making Schottky contact with the emitter layer.

### BRIEF DESCRIPTION OF THE DRAWINGS

FIGS. 1A and 1B each shows the structure of a hetero-junction bipolar transistor according to the present invention; and

FIGS. 2A to 2G are cross-sectional views each showing a process of the manufacturing method of the hetero-junction bipolar transistor according to the present invention.

### DESCRIPTION OF THE EMBODIMENT

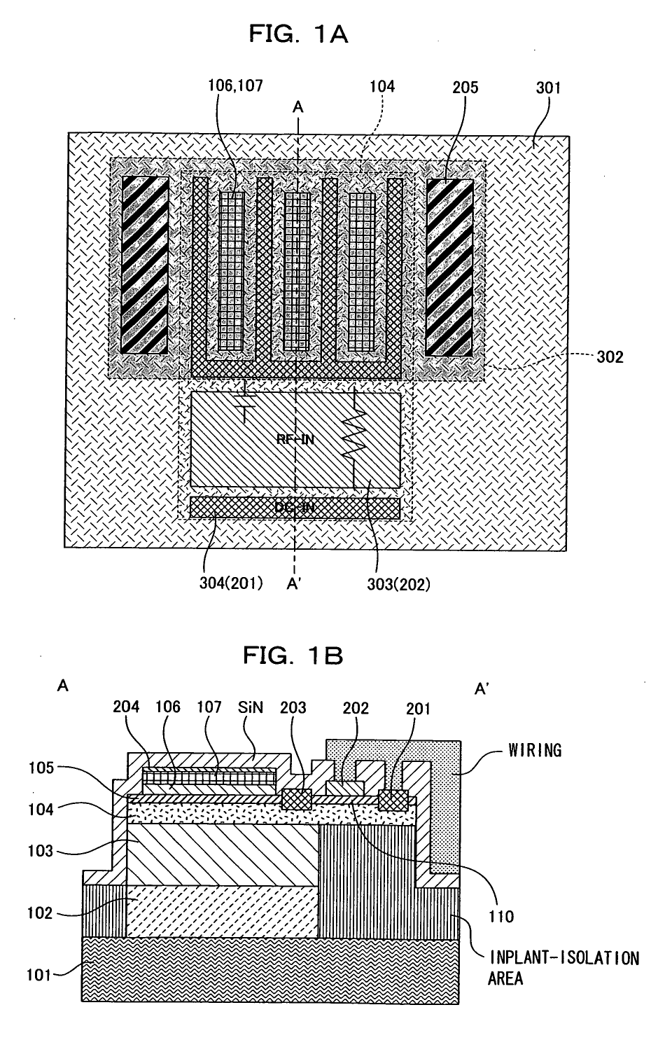

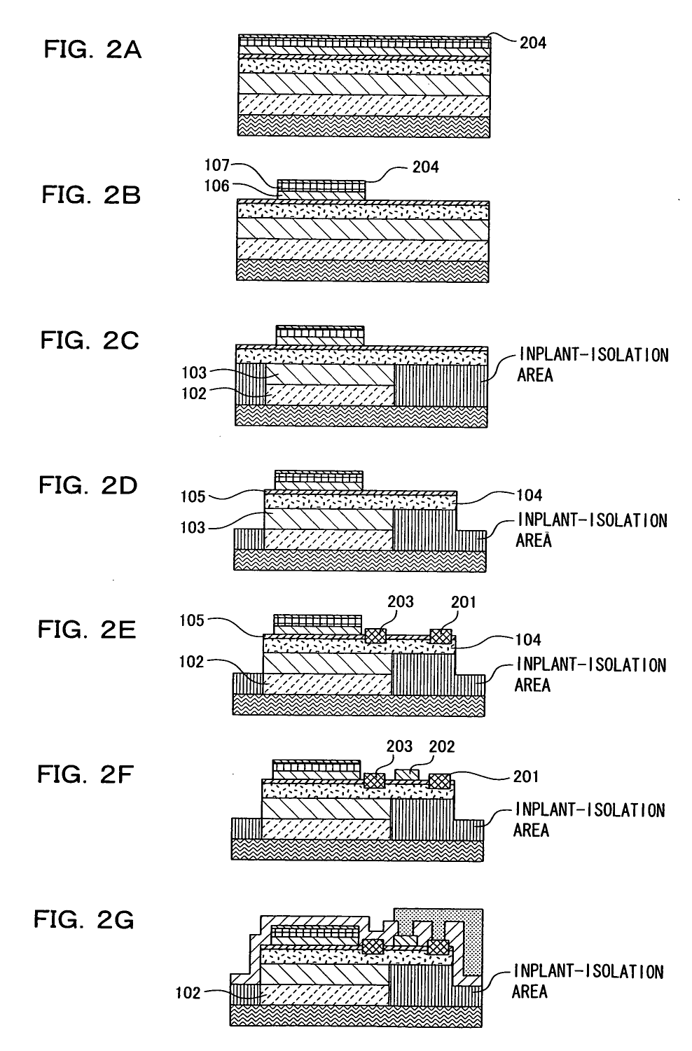

Referring to FIGS. 1A and 1B and FIGS. 2A to 2G, the following will specifically describe embodiments of a hetero-junction bipolar transistor according to the present invention.

FIGS. 1A and 1B each is a diagram showing the structure of the hetero-junction bipolar transistor according to the present invention. FIG. 1A is a plan view and FIG. 1B is a cross sectional view taken along line A-A′ of the plan view of FIG. 1A. FIGS. 2A to 2G each is a cross-sectional view showing a process of the manufacturing method of the hetero-junction bipolar transistor according to the present invention. The cross sections are taken at the same position as that of FIG. 1B.

As shown in FIGS. 1A and 1B, the hetero-junction bipolar transistor is basically configured as follows: an n+ type GaAs sub-collector layer 102 doped with a high-concentration n-type impurity, a 500 nm thick collector layer 103 made of GaAs doped with a low-concentration n-type impurity, a 100 nm thick GaAs base layer 104 doped with a p-type impurity, and a 30 nm thick In0.48GaP emitter layer 105 doped with an n-type impurity with an In composition ratio of about 48% are stacked in this order on a semi-insulating GaAs substrate 101.

Further, a 200 nm thick GaAs emitter cap layer 106 doped with an n-type impurity and a 100 nm thick InGaAs emitter contact layer 107 doped with an n-type impurity are stacked on the emitter layer 105. These laminated structures form a two-level protrusion on the sub-collector layer 102.

On the base layer 104, an area where the emitter layer 105, the emitter cap layer 106, and the emitter contact layer 107 are present contributes to a transistor operation as an intrinsic base area. The other area is an external base area not acting as a base.

In the external base area, the emitter layer 105 formed on the area 303 acts as a capacitance film 110, an upper electrode 202 of the capacitance film is formed thereon, and the first base electrode 201 is diffused and formed from the above of the emitter layer 105 to the base layer 104 in an area 304 of the other area. The area 304 is far from the intrinsic area in the other area.

The collector layer 103 and the sub-collector layer 102 under the area 303 and the area 304 are increased in resistance or insulated by ion implantation. Thus, the area 303 and the area 304 do not contribute as a collector-base capacitance, so that high frequency characteristics are not degraded.

In the upper electrode 202 of the capacitance film 110, a metal such as Mo, W, and WSi is formed. The metal has a high contact resistance relative to InGaP forming the capacitance film 110, so that a Schottky barrier is formed.

The first base electrode 201 is brought into Ohmic contact by thermal diffusion of Pt, Pd, or the like from the above of InGaP forming the emitter layer 105.

A WSi 204 acting as an emitter electrode is formed on InGaAs forming the emitter contact layer 107.

The emitter layer 105 and the base layer 104 are removed in an area other than the intrinsic base area and the external base area.

The collector layer 103 and the sub-collector layer 102 are increased in resistance or insulated by ion implantation in an area other than the intrinsic area acting as an HBT.

In the external base area, the capacitance film 110 and the first base electrode 201 are formed in an area 301 where the collector layer 103 and the sub-collector layer 102 are insulated, and a second base electrode 203 is formed in an area 302 where the collector layer 103 and the sub-collector layer 102 are not insulated.

The intrinsic base area and a collector electrode 205 are formed in the area 302 where the collector layer 103 and the sub-collector layer 102 are not insulated.

Since a high-frequency input signal from the upper electrode 202 is inputted to the intrinsic base area through the capacitance film 110, high-frequency characteristics are not degraded by the resistance of the external base area. Further, an external base resistor can be used as a ballast resistor by inputting direct current from the first base electrode 201, thereby improving thermal stability.

Since the sub-collector layer 102 under the external base area is insulated by ion implantation, a parasitic capacitance between the base and collector is not increased and thus high-frequency characteristics are not degraded.

The second base electrode 203 is formed between the intrinsic base area and the capacitance film, thereby reducing a base resistance in the intrinsic area. In this case, it is desirable that ion implantation is not performed under the second base area 203. Hence, the base resistance of the intrinsic area does not increase.

The capacitance film 110 is made of InGaP or AlGaAs forming the emitter layer 105, and the upper electrode 202 of the capacitance film 110 is made of a metal forming a Schottky barrier against InGaP and AlGaAs, so that the emitter layer can be used as a capacitance film. In this case, InGaP or AlGaAs forms a thin film having a thickness of 30 to 50 nm and thus the capacitance film 110 can be formed with quite a small area. Further, since InGaP enables selective etching, high mass production can be obtained for the capacitance film.

Another advantage is that the area of the ballast resistor can be reduced by high resistance obtained by ion implantation on the base layer 104.

A base sheet resistance can be also controlled by a technique such as multi-stage implantation.

In the embodiment of the present invention, the second base electrode 203 is formed and the second base layer may not be formed.

The collector layer 103 and the sub-collector layer 102 under the second base electrode 203 are not insulated. The second base electrode 203 may be formed near a boundary between the intrinsic base area and the external base area having been insulated by ion implantation.

InGaP is used as the emitter layer in the present embodiment. Other semiconductor materials including AlGaAs may be used.

The scope of the present invention is not particularly limited by numeric values such as a thickness.

Referring to FIGS. 1 and 2, the following will describe the manufacturing method of the hetero-junction bipolar transistor according to the present invention.

First, the n+ type GaAs sub-collector layer 102 doped with a high-concentration n-type impurity, the 500 nm thick collector layer 103 made of GaAs doped with a low-concentration n-type impurity, the 100 nm thick GaAs base layer 104 doped with a p-type impurity, and the 30 nm thick In0.48GaP emitter layer 105 doped with an n-type impurity with an In composition ratio of about 48% are stacked in this order on the semi-insulating GaAs substrate 101.

Further, the 200 nm thick GaAs emitter cap layer 106 doped with an n-type impurity and the 100 nm thick InGaAs emitter contact layer 107 doped with an n-type impurity are stacked on the emitter layer 105.

According to the present invention, in this structure, the WSi 204 is formed as an emitter metal by overall vapor deposition as shown in FIG. 2A.

In FIG. 2B, etching is performed by lithography and dry etching on the WSi 204 acting as an emitter electrode in a part other than the emitter area of the hetero-junction bipolar transistor, and the exposed emitter contact layer 107 and emitter cap layer 106 are removed by wet etching.

Etching is performed on GaAs by using a mixed solution of H₃PO₄:H₂O₂:H₂O=4:1:45 as a wet etching solution. In this etching solution, a selection ratio of GaAs to InGaP is almost infinite, and thus the remaining film of InGaP can be controlled with extremely high accuracy.

In FIG. 2C, another mask pattern is formed, ion implantation is performed on the area 303 other than the intrinsic transistor area, and the collector layer 103 and the sub-collector layer 102 in this part are electrically insulated.

This step also includes device isolation between transistors and the isolation of the collector layer 103 and the sub-collector layer 102 under the capacitance film.

For example, He ions or H ions are implanted with a dose of 6E13 and an acceleration voltage of 200 KeV or higher, e.g., 250 KeV.

In FIG. 2D, the base layer 104, the emitter layer 105, and the collector layer 103 are removed by etching in a part other than the intrinsic base area and the external base area.

In FIG. 2E, in the external base area, the first base electrode 201 far from the intrinsic base area and the second base electrode 203 near the intrinsic base area are formed at the same time. At this point, Pt/Ti/Pt/Au=30/50/50/100 nm is formed as the base electrodes, and contact is made by thermal diffusion, through InGaP forming the emitter layer 105, with the base layer 104 formed below. Other materials such as Pd can be also used.

The first base electrode 201 is formed in the area 301 where the sub-collector layer 102 is insulated, and the second base electrode 203 is formed in the area 302 where the sub-collector layer 102 is not insulated.

In FIG. 2F, in the external base area, an Mo/Ti/Au electrode acting as the upper electrode 202 of the capacitance film is formed between the first base electrode 201 and the second base electrode 203.

Since Mo is a metal making Schottky contact with InGaP, InGaP of the emitter layer acts as the capacitance film 110.

Although Mo is used in the present embodiment, any metal can be used as long as the metal makes Schottky contact with InGaP. For example, the same effect can be obtained using a metal such as W and WSi.

In FIG. 2G, the HBT is completed after the step of forming the collector electrode on the sub-collector layer 102, the step of forming p-SiN as an interlayer film, the step of forming an opening on the insulating film on the capacitive upper electrode and the emitter, base, collector, and electrodes of the HBT, and the step of drawing wires from the electrodes. The detailed explanation of the steps is omitted.

These steps make it possible to manufacture the hetero-junction bipolar transistor with a small area, excellent high-frequency characteristics, and high thermal stability.

In the ion implantation, He ions are implanted at an acceleration voltage of 250 KeV. With two-stage implantation using B ions at a low acceleration voltage, it is possible to adjust the sheet resistance value of the base layer formed under the capacitance film used as a ballast resistor.

The external base electrode is formed by thermal diffusion from the above of InGaP. Direct contact can be made with the base layer by removing InGaP.

InGaP is used as the capacitance film. InGaP has high selectivity relative to GaAs and causes few variations in the thickness of the capacitance film, thereby achieving a capacitance value enabling extremely high reproducibility.

Moreover, a base sheet resistance can be controlled by a technique such as multi-stage implantation.

What is claimed is:

1. A hetero-junction bipolar transistor comprising a substrate and semiconductor layers stacked on the substrate,
said transistor comprising:
a sub-collector layer of a first conductivity type formed on the substrate,
a collector layer of the first conductivity type formed on the sub-collector layer,
a base layer of a second conductivity type formed on the collector layer and including an intrinsic base area and an external base area,
an emitter layer of the first conductivity type formed on the intrinsic base area,
a capacitance film formed on the external base area,
an upper electrode formed on the capacitance film, and
a first base electrode formed in the external base area, wherein
ion implantation is performed on the sub-collector layer and the collector layer under the capacitance film.

2. The hetero-junction bipolar transistor according to claim 1, wherein the sub-collector layer and collector layer under the capacitance film are electrically insulated by ion implantation.

3. The hetero-junction bipolar transistor according to claim 1, wherein the first base electrode is formed in an area at a fixed distance or more from a boundary of the external base area and the intrinsic base area.

4. The hetero-junction bipolar transistor according to claim 1, wherein the transistor further comprises a second base area formed near the boundary of the external base area and the intrinsic base area, and the capacitance film is formed between the first base electrode and the second base electrode.

5. The hetero-junction bipolar transistor according to claim 4, further comprising a non-ion implantation area formed under the second base electrode.

6. The hetero-junction bipolar transistor according to claim 1, wherein the capacitance film is made of a semiconductor material of the first conductivity type.

7. The hetero-junction bipolar transistor according to claim 1, wherein the capacitance film is formed by extending the emitter layer to the external base area.

8. The hetero-junction bipolar transistor according to claim 1, wherein the capacitance film is made of InGaP or AlGaAs.

9. The hetero-junction bipolar transistor according to claim 1, wherein the upper electrode is made of a metal making Schottky contact with the emitter layer.

10. A manufacturing method of a hetero-junction bipolar transistor comprising a substrate and semiconductor layers stacked on the substrate, the method comprising:
forming a sub-collector layer of a first conductivity type on the substrate,
forming a collector layer of the first conductivity type on the sub-collector layer,
forming on the collector layer a base layer of a second conductivity type including an intrinsic base area and an external base area,
forming an emitter layer of the first conductivity type on the intrinsic base area,
forming a capacitance film on the external base area,
implanting ions into the sub-collector layer and the collector layer under the capacitance film,
forming an upper electrode on the capacitance film, and
forming a first base electrode in the external base area.

11. The manufacturing method of the hetero-junction bipolar transistor according to claim 10, wherein implantation ion species are He or H ions, and the method comprises at least performing ion implantation at an acceleration voltage of not lower than 200 keV.

12. The manufacturing method of the hetero-junction bipolar transistor according to claim 10, further comprising forming a second base area near a boundary of the external base area and the intrinsic base area.

13. The manufacturing method of the hetero-junction bipolar transistor according to claim 12, wherein the second base electrode is formed on the base area where ion implantation is not performed.

14. The manufacturing method of the hetero-junction bipolar transistor according to claim 10, wherein the emitter layer is made of InGaP or AlGaAs and the emitter layer is formed by selective etching.

15. The manufacturing method of the hetero-junction bipolar transistor according to claim 12, wherein the first base electrode and the second base electrode are made of Pt or Pd and diffused by thermal diffusion from above the capacitance film to the base layer.

16. The manufacturing method of the hetero-junction bipolar transistor according to claim 10, wherein the upper electrode is made of a metal making Schottky contact with the emitter layer.
